(19) United States
(12) Patent Application Publication
(10) Pub. No.: US 2026/0204891 A1
(43) Pub. Date: Jul. 16, 2026

(54) LEAKAGE PROTECTION CIRCUIT WITH NOISE FILTER

(71) Applicant: Wise Ally Holdings Limited, Hong Kong (CN)

(72) Inventors: Keung CHAU, Hong Kong (CN); Chi Man FUNG, Hong Kong (CN)

(73) Assignee: Wise Ally Holdings Limited, Hong Kong (CN)

(21) Appl. No.: 19/021,295

(22) Filed: Jan. 15, 2025

(51) Int. Cl. H02H 3/087; H02H 1/00; H03H 1/02

(52) U.S. Cl. CPC H02H 3/087; H02H 1/0007; H03H 1/02

(57) ABSTRACT

A leakage protection circuit with noise filtering, comprises a leakage protection circuit. The input of the leakage protection circuit is connected in series with a noise filtering circuit before being connected to the power supply, and the output of the leakage protection circuit is connected to the electrical equipment. When a leakage occurs in the electrical device, the differential signals generated in the power line are directly detected by the leakage protection circuit, and allow for timely power cutoff. The operation will not be affected by the functioning of the noise filtering circuit and help to avoid false trigger and improve the response time of the leakage protection circuit.

### FIELD OF THE INVENTION

The present invention relates to a power protection circuit, specifically a leakage protection circuit with noise filtering.

### BACKGROUND OF THE INVENTION

In order to ensure the safety of electrical equipment, typically it is necessary to equip a leakage monitoring and protection circuits. Once there is a leakage in the electrical device, the leakage monitoring and protection circuit can immediately cut off the power supply to prevent potential electric shock hazards to users. Additionally, different electrical devices generate high-frequency signals during operation, such as those from a high-frequency switch power supply. Such high-frequency signals can feedback into the power lines, potentially interfering with other electrical devices. Therefore, a noise filtering circuit needs to be installed at the power input of the electrical device. The existing circuit usually set the noise filtering circuit at the output of the leakage protection circuit. However, since components like capacitors or inductors are very common in the noise filtering circuit, these components may filter or delay the differential signals while there is leakage in the power lines. Furthermore, charging and discharging of the capacitors or inductors in the noise filtering circuit might lead to generate fake differential signals, and then affect the sensitivity, response time, or cause false triggers in the leakage protection circuit.

### SUMMARY OF THE INVENTION

The present invention is to provide a leakage protection circuit with noise filtering for improving the overall reliability of the circuit by adjusting the configuration of the noise filtering circuit and the leakage protection circuit.

The present invention is realized by the following technical solutions:

A leakage protection circuit with noise filtering, comprising a leakage protection circuit, the input of which is connected in series with a noise filtering circuit before being connected to the power supply, and the output of the leakage protection circuit is connected to the electrical equipment.

Further, the leakage protection circuit includes an inductance sampling circuit, a leakage monitoring chip, and a peripheral circuit; the inductance sampling circuit consists of a current transformer and a filtering circuit; the output power supply lines of the noise filtering circuit pass through the current transformer in parallel; the output of the current transformer is connected to the filtering circuit and then connected to a differential signal input of the leakage monitoring chip, the output power supply line of the noise filtering circuit is connected in series with a relay before being output to the electrical equipment, the suction coil of the relay is connected to the control output of the leakage monitoring chip.

Further, the number of the noise filtering circuit is two, each of the noise filtering circuit consists of eight resistors and a capacitor connected in series at input of the power supply.

Further, the leakage monitoring chip is NC37020 or FM2159.

The beneficial effects of the present invention are: when there is a leakage occurring in the electrical device, the differential signals generated in the power line are directly detected by the leakage protection circuit to timely cutoff power. This operation is not affected by the functioning of the noise filtering circuit, which helps avoid false triggers and improves the response time of the leakage protection circuit.

### BRIEF DESCRIPTION OF THE DRAWINGS

To more clearly illustrate the technical solutions in the embodiments of the present invention, the techniques in the embodiments are described in detail below together with the following drawings.

FIG. 1 is the circuit diagram of the first embodiment of the present invention;

FIG. 2 is the circuit diagram of the second embodiment of the present invention.

### DESCRIPTION OF THE EMBODIMENTS

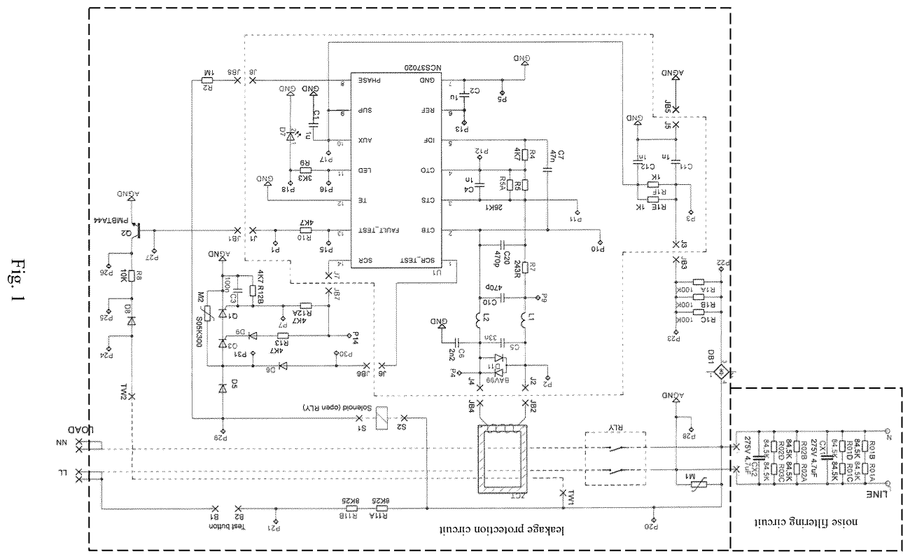

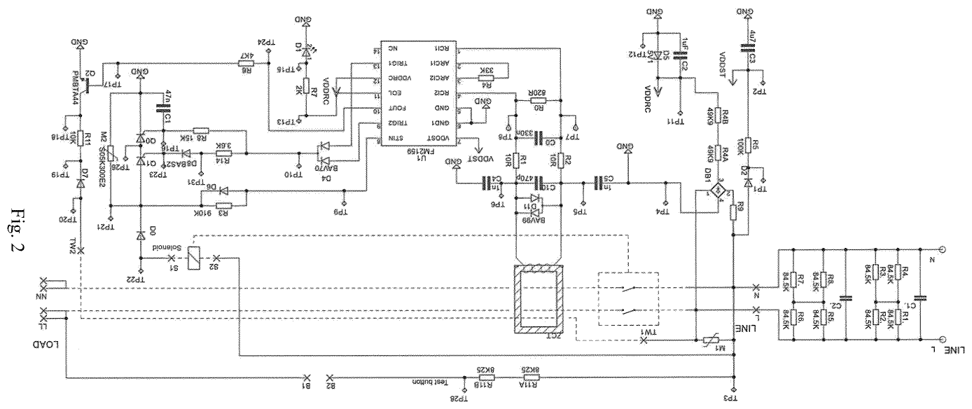

Referring to FIG. 1 and FIG. 2, the leakage protection circuit with noise filtering, comprises a leakage protection circuit. The input of the leakage protection circuit is connected in series with the noise filtering circuit before being connected to a power supply, and the output of the leakage protection circuit is connected to the power consumption equipment. If a power leakage occurs in the power consumption equipment, the differential signals is generated in the power line, directly detected by the leakage protection circuit, and allow the circuit cutoff the power timely. The operation will not be affected by the functioning of the noise filtering circuit, and avoid false trigger and improve the response time of the leakage protection circuit.

Wherein, the leakage protection circuit includes the inductance sampling circuit, the leakage monitoring chip and the peripheral circuit. The peripheral circuit include the power supply circuit, the output drive circuit, the status display circuit, etc. The power supply circuit is connected to the power supply and generates DC power for the leakage monitoring chip through rectifier bridges and filter circuits, etc. The coil of the relay requires an operating current, but the output of the leakage detection chip does not provide enough driving current, so it is necessary to use an output driver circuit which includes a SCR and a peripheral circuit, the relay coil is connected to the output driver circuit. There is also a status display circuit, etc. When there is a leakage or abnormality, the corresponding port of the leakage monitoring chip output signal to drive the LED informing the user to deal with in time. The inductance sampling circuit consists of a current transformer and a filtering circuit. The output power supply lines of the noise filtering circuit pass through the current transformer in parallel. The output of the current transformer is connected to the filtering circuit and then connected to a differential signal input of the leakage monitoring chip. The output power supply line of the noise filtering circuit is connected in series with a relay before being output to the electrical equipment, the suction coil of the relay is connected to the control output of the leakage monitoring chip. The leakage monitoring chip is NC37020 or FM2159.

Additionally, the number of the noise filtering circuit is two, each of the noise filtering circuit consists of eight resistors and a capacitor connected in series at input of the power supply. It is used to filter high frequency noise signals generated by electrical equipment to prevent from coupling to the power line and affecting the work of other electrical equipment.

1. A leakage protection circuit with noise filtering, comprising a leakage protection circuit, the input of which is connected in series with a noise filtering circuit before being connected to the power supply, and the output of the leakage protection circuit is connected to the electrical equipment.

2. The leakage protection circuit with noise filtering of claim 1, wherein the leakage protection circuit includes an inductance sampling circuit, a leakage monitoring chip, and a peripheral circuit; the inductance sampling circuit consists of a current transformer and a filtering circuit; the output power supply lines of the noise filtering circuit pass through the current transformer in parallel; the output of the current transformer is connected to the filtering circuit and then connected to a differential signal input of the leakage monitoring chip, the output power supply line of the noise filtering circuit is connected in series with a relay before being output to the electrical equipment, the suction coil of the relay is connected to the control output of the leakage monitoring chip.

3. The leakage protection circuit with noise filtering of claim 1, wherein the number of the noise filtering circuit is two, each of the noise filtering circuit consists of eight resistors and a capacitor connected in series at input of the power supply.

4. The leakage protection circuit with noise filtering of claim 2, wherein the leakage monitoring chip is NC37020 or FM2159.
